(19) United States
(12) Patent Application Publication
(10) Pub. No.: US 2007/0278000 A1
(43) Pub. Date: Dec. 6, 2007

(54) Component-embedded printed wiring board, manufacturing method for component-embedded printed wiring board, and electronic apparatus

(76) Inventors: Daigo Suzuki, Yokohama-shi (JP); Jun Karasawa, Tokyo (JP); Hidenori Tanaka, Hachioji-shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/807,425

(22) Filed: May 29, 2007

(30) Foreign Application Priority Data
May 30, 2006 (JP) 2006-150030

(51) Int. Cl. H05K 1/16; H05K 7/00

(52) U.S. Cl. 174/260; 361/760

(57) ABSTRACT

According to one embodiment, a component-embedded printed wiring board includes a base including a component mounting surface, a pair of conductive patterns which is disposed on the component mounting surface of the base, and a circuit component which is mounted on the base so as to be in close contact with the component mounting surface between the conductive patterns and electrically connected to the conductive patterns.

### CROSS-REFERENCE TO RELATED APPLICATIONS

This application is based upon and claims the benefit of priority from Japanese Patent Application No. 2006-150030, filed May 30, 2006, the entire contents of which are incorporated herein by reference.

### BACKGROUND

1. Field

One embodiment of the invention relates to a component-embedded printed wiring board having a chip component to be incorporated in an electronic circuit, a manufacturing method for the component-embedded printed wiring board, and an electronic apparatus.

2. Description of the Related Art

Small electronic apparatuses, such as portable computers, personal digital assistants, etc., require use of boards capable of high-density wiring and a reliable technique for mounting components on boards.

A component-embedded printed wiring board having a chip component to be incorporated in an electronic circuit is a type of printed wiring board used in an electronic apparatus (Jpn. Pat. Appln. KOKAI Publication No. 2002-232145). As a technique for manufacturing the component-embedded printed wiring board of this type, there is a method in which a component mounting hole is formed in an insulating board, and circuit components, such as capacitors, resistance elements, etc., are set in the hole (Jpn. Pat. Appln. KOKAI Publication No. 11-74648).

If voids (air or gas pools) are formed in a gap between the chip component and a component mounting surface portion, in the component-embedded printed wiring board, they are heated by heat treatment thereafter or by heat received after the board is incorporated into the electronic apparatus. Thermal expansion of the voids may possibly cause various troubles, such as separation of conductive patterns, damage to the chip component, circuit disconnection, lowering of the board stiffness, etc.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1A, FIG. 1B, FIG. 1C, FIG. 1D, FIG. 1E, FIG. 1F and FIG. 1G are exemplary sectional side views showing manufacturing processes for a component-embedded printed wiring board according to a first embodiment of the invention;

FIG. 2A, FIG. 2B,. FIG. 2C, FIG. 2D, FIG. 2E, FIG. 2F and FIG. 2G are exemplary sectional side views showing manufacturing processes for a component-embedded printed wiring board according to a second embodiment of the invention;

FIG. 3A, FIG. 3B, FIG. 3C, FIG. 3D, FIG. 3E, FIG. 3F, FIG. 3G and FIG. 3H are exemplary sectional side views showing manufacturing processes for a component-embedded printed wiring board according to a third embodiment of the invention;

FIG. 4 is an exemplary sectional side view showing a configuration of a principal part of a component-embedded printed wiring board according to a fourth embodiment of the invention;

FIG. 5 is an exemplary sectional side view showing a configuration of a principal part of a component-embedded printed wiring board according to a fifth embodiment of the invention;

FIG. 6A is an exemplary perspective view showing a configuration of an electronic apparatus according to any of the embodiments of the invention; and

FIG. 6B is an exemplary sectional view showing a printed board contained in the electronic apparatus shown in FIG. 6A.

### DETAILED DESCRIPTION

Various embodiments according to the invention will be described hereinafter with reference to the accompanying drawings. In general, according to one embodiment of the invention, a component-embedded printed wiring board includes a base including a component mounting surface, a pair of conductive patterns which is disposed on the component mounting surface of the base, and a circuit component which is mounted on the base so as to be in close contact with the component mounting surface between the conductive patterns and electrically connected to the conductive patterns.

### First Embodiment

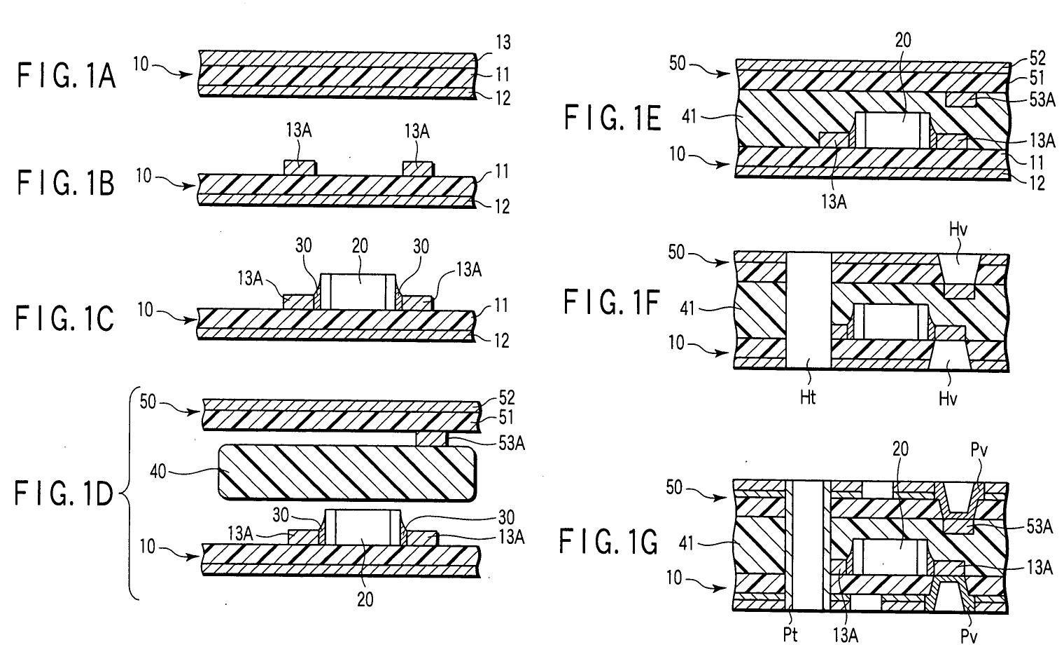

A component-embedded printed wiring board according to a first embodiment of the invention will be described together with manufacturing processes therefor with reference to FIGS. 1A to 1G.

FIGS. 1A to 1G show the manufacturing processes for the component-embedded printed wiring board according to the first embodiment of the invention. FIG. 1G shows a configuration of the component-embedded printed wiring board of the first embodiment, a product manufactured by the manufacturing processes.

As shown in FIG. 1G, the component-embedded printed wiring board according to the first embodiment of the invention comprises a first base 10, a resin material 41, a second base 50 that serves as another member, and a circuit component 20 to form an embedded chip component.

The first and second bases 10 and 50 have an insulating base and electrically conductive layers that form electrically conductive patterns individually on the opposite surfaces of the insulating base. The inner layer side of the first base 10 has a component mounting surface on which a plurality of electrically conductive patterns 13A are arranged to serve as component joining electrodes. These conductive patterns 13A may be either electrode pads that constitute the component joining electrodes or some of wiring patterns. The top and side surfaces of each conductive pattern 13A form electrode junction surfaces of the circuit component 20.

The second base 50, another member, is laminated over the first base 10 with the insulating layer 41 between them.

The circuit component 20 is a chip component that is composed of a component body in the shape of a rectangular parallelepiped and a pair of terminals thereon. Thus, the circuit component 20 is in the form of a rectangular parallelepiped including the terminals on the opposite ends of the component body. Although two-terminal passive elements, such as resistance elements, capacitor elements, etc., are illustrated as examples of embedded chip components according to this embodiment, they may be replaced with passive or active elements with three or more terminals.

The circuit component 20 is mounted on the first base 10 in a manner such that it is located in close contact with the inner component mounting surface of the first base 10 between the paired conductive patterns 13A on the mounting surface.

Specifically, the pair of conductive patterns 13A to which the circuit component 20 is soldered are located with a space therebetween for holding the circuit component 20 on the component mounting surface. The circuit component 20 is provided between the conductive patterns 13A. Electrodes at the opposite ends of the circuit component 20 are soldered to side faces of the conductive patterns 13A. In the embodiment shown in FIG. 1G, one of the electrodes at the opposite ends of the circuit component 20 is circuit-connected to a through plug Pt that circuit-connects layers, and the electrode on the other end side is circuit-connected to via plugs Pv.

Thus, in the wiring board structure of the first embodiment shown in FIG. 1G, the circuit component 20 is in close contact with the component mounting surface when it is mounted on the first base 10, so that no gap to produce voids is formed between the component 20 and the mounting surface of the first base 10. Even if the wiring board is heated by heat treatment during its manufacture or by heat received after it is incorporated into an electronic apparatus, therefore, there is no possibility of air or gas in voids being thermally expanded and causing separation of the conductive patterns, damage to the chip component, circuit disconnection, lowering of the board stiffness, etc.

If any gap is formed between the circuit component and the component mounting surface, it must be filled up with the resin material to prevent formation of voids therein lest the various troubles attributable to voids be avoided. In the wiring board structure of the first embodiment described above, the circuit component 20 is in close contact with the component mounting surface when it is mounted on the first base 10. Depending on the shape of the mounted circuit component 20, however, a gap may be formed between the circuit component 20 and the component mounting surface. However, voids that are formed in this gap are much smaller than those in a conventional component mounting structure in which the circuit component is mounted on the conductive patterns (pattern surfaces) by soldering. Therefore, the voids can be filled up with a very small amount of resin material. If a low-viscosity resin material (filling material or adhesive material) is used to attain this, moreover, the voids can be filled up in a simple process without requiring any filling means such as spraying or compressing means, since the voids are permeated and impregnated with the material by capillarity.

In the wiring board structure of the first embodiment shown in FIG. 1G, furthermore, the circuit component 20 is located between the conductive patterns 13A that are formed on the component mounting surface of the first base 10, and is in close contact with the mounting surface of the first base 10 when it is mounted thereon. Therefore, the wiring board can be made thinner than the component mounting structure in which the circuit component is mounted on the conductive patterns (pads) by soldering. Since the circuit component 20 is in close contact with the component mounting surface of the first base 10 when it is mounted thereon, moreover, a thin chip component can be prevented from being broken or damaged under pressure during lamination if it is mounted as the circuit component 20.

In the component mounting structure in which the circuit component is mounted on the pads by soldering, the circuit component is prevented from being broken or damaged under external stress by being covered by a stress relieving material. In the wiring board of the first embodiment shown in FIG. 1G, on the other hand, the circuit component 20 is in close contact with the component mounting surface of the first base 10, so that it can be protected from external stress without being covered by any stress relieving material, and the wiring board can be reduced in thickness.

The component-embedded printed wiring board described above is manufactured by the processes shown in FIGS. 1A to 1G.

As shown in FIG. 1A, the first base 10 is prepared having conductive layers 12 and 13 for the formation of the conductive patterns on the opposite surfaces of a prepreg sheet 11. The second base 50 is prepared in like manner.

As shown in FIG. 1B, the pair of conductive patterns 13A are formed on the previously designed component mounting surface on the inner layer side of the first base 10 by selectively removing the conductive layer 13. The space between the conductive patterns 13A is designed so that the mounted component can be confined thereto. The second base 50 is also formed with conductive patterns that comply with the pattern design requirements.

As shown in FIG. 1C, the circuit component 20 is set on that part of the component mounting surface between the conductive patterns 13A. The circuit component 20 is mounted on the component mounting surface of the first base 10 by bonding the electrodes of the component 20 to the conductive patterns 13A with a solder 30 in a manner such that the component 20 is in close contact with the mounting surface. If a gap is formed between the circuit component 20 and the component mounting surface, depending on the shape of the mounted component 20, it is filled up with a low-viscosity filling or adhesive material.

As shown in FIG. 1D, the resin material 41 and the second base 50 are laminated on a pattern forming surface on the inner layer side of the first base 10. The pattern forming surface of the first base 10 is located opposite that surface of the second base 50 on which a conductive pattern 53A is formed.

As shown in FIG. 1E, the laminated members are integrated by being heated and pressurized. Thereupon, the second base 50 is laminated and integrated together with the first base 10 with the resin material 41 between them.

As shown in FIG. 1F, a through hole Ht, via holes Hv, etc. are formed in the component-embedded printed wiring board including the integrated members by hole boring based on drilling or laser machining.

As shown in FIG. 1G, the through hole Ht and the via holes Hv, which are bored in the process shown in FIG. 1F, and the respective surface layers (outermost layers) of the first and second bases 10 and 50 are subjected to plating and wiring. Thereupon, the through plug Pt and the via plugs Pv are formed together with a necessary circuit wiring pattern for the electronic apparatus that uses the component-embedded printed wiring board. Thus, the component-embedded printed wiring board is realized having the necessary circuit wiring pattern for the electronic apparatus.

Since the circuit component 20 is in close contact with the component mounting surface when the component-embedded printed wiring board is mounted on the first base 10, no gap to produce voids is formed between the component 20 and the mounting surface of the first base 10. Therefore, the various troubles attributable to voids can be avoided to realize the high-reliability component-embedded printed wiring board. Since the circuit component 20 is mounted in close contact with the component mounting surface of the first base 10 between the conductive patterns 13A on the mounting surface, the wiring board can be reduced in thickness. Since the circuit component 20 is in close contact with the component mounting surface of the first base 10 when it is mounted thereon, moreover, a thin chip component can be prevented from being broken or damaged under pressure during lamination if it is mounted as the circuit component 20.

### Second Embodiment

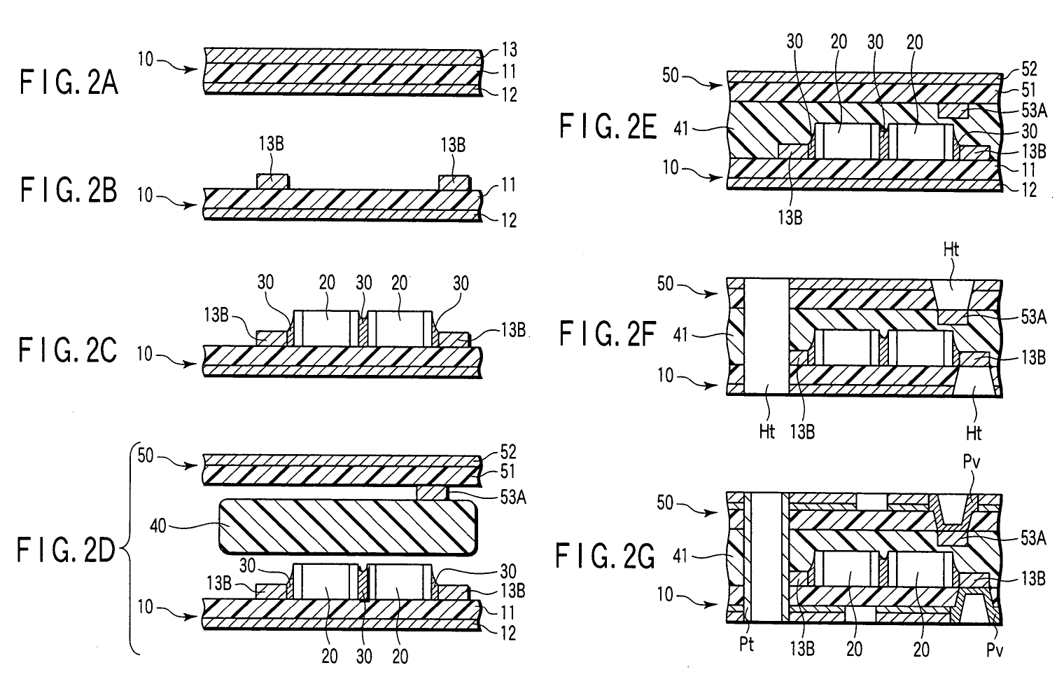

A component-embedded printed wiring board according to a second embodiment of the invention will be described together with manufacturing processes therefore with reference to FIGS. 2A to 2G.

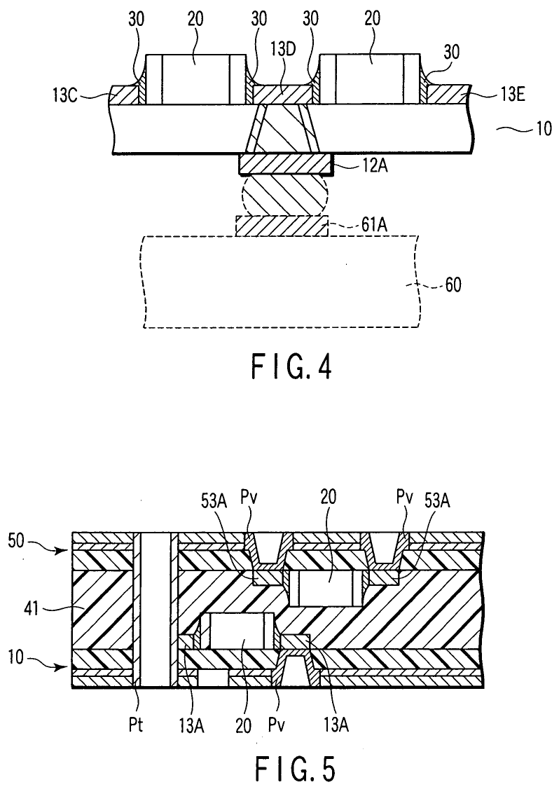

FIGS. 2 and 4 show the manufacturing processes for the component-embedded printed wiring board according to the second embodiment of the invention. FIG. 2G shows a configuration of the component-embedded printed wiring board of the second embodiment, a product manufactured by the manufacturing processes.

As shown in FIG. 2G, the component-embedded printed wiring board according to the second embodiment of the invention comprises a first base 10, a resin material 41, a second base 50 that serves as another member, and a plurality of (e.g., two) circuit components 20 to form embedded chip components.

The first and second bases 10 and 50 and the resin material 41 are individually composed of the same members as the ones according to the first embodiment.

Electrically conductive patterns 13B are formed on a component mounting surface on the inner layer side of the first base 10 with a space therebetween for holding the two circuit components 20 in series with each other.

The two circuit components 20 are set in series with each other between the conductive patterns 13B that are formed on the component mounting surface of the first base 10. The components 20 are individually in close contact with the component mounting surface when they are mounted on the first base 10.

Thus, in the wiring board structure of the second embodiment shown in FIG. 2G, the two circuit components 20 are individually in close contact with the component mounting surface when they are mounted on the first base 10, so that no gaps to produce voids are formed between the components 20 and the mounting surface of the first base 10. Even if any gaps are formed, therefore, they are so narrow that they can be filled up with a small amount of filling (or adhesive) material. Accordingly, the various troubles attributable to voids can be avoided to realize the high-reliability component-embedded printed wiring board. Since the two circuit components 20 are mounted in close contact with the component mounting surface of the first base 10 between the conductive patterns 13B on the mounting surface, the wiring board can be reduced in thickness. Since the circuit components 20 are in close contact with the component mounting surface of the first base 10 when they are mounted thereon, moreover, thin chip components can be prevented from being broken or damaged under pressure during lamination if they are mounted as the circuit components 20.

The component-embedded printed wiring board according to the second embodiment described above is manufactured by the processes shown in FIGS. 2A to 2G.

As shown in FIG. 2A, the first base 10 is prepared having conductive layers 12 and 13 for the formation of the conductive patterns on the opposite surfaces of a prepreg sheet 11. The second base 50 is prepared in like manner.

As shown in FIG. 2B, the pair of conductive patterns 13B are formed on the previously designed component mounting surface on the inner layer side of the first base 10 by selectively removing the conductive layer 13. The space between the conductive patterns 13B is designed so that the two circuit components 20 can be confined thereto. The second base 50 is also formed with conductive patterns that comply with the pattern design requirements.

As shown in FIG. 2C, the two circuit components 20 are set in series with each other between the conductive patterns 13B. The circuit components 20 are mounted on the component mounting surface of the first base 10 by bonding electrodes of the components 20 to one another and to the conductive patterns 13B with a solder 30 in a manner such that the components 20 are individually in close contact with the mounting surface. If gaps are formed between the circuit components 20 and the component mounting surface, depending on the shape of the mounted components 20, they are filled up with a low-viscosity filling or adhesive material.

As shown in FIG. 2D, the resin material 41 and the second base 50 are laminated on a pattern forming surface on the inner layer side of the first base 10. The pattern forming surface of the first base 10 is located opposite that surface of the second base 50 on which a conductive pattern 53A is formed.

As shown in FIG. 2E, the laminated members are integrated by being heated and pressurized. Thereupon, the second base 50 is laminated and integrated together with the first base 10 with the resin material 41 between them.

As shown in FIG. 2F, a through hole Ht, via holes Hv, etc. are formed in the component-embedded printed wiring board including the integrated members by hole boring based on drilling or laser machining.

As shown in FIG. 2G, the through hole Ht and the via holes Hv, which are bored in the process shown in FIG. 2F, and the respective surface layers (outermost layers) of the first and second bases 10 and 50 are subjected to plating and wiring. Thereupon, the through plug Pt and the via plugs Pv are formed together with a necessary circuit wiring pattern for the electronic apparatus that uses the component-embedded printed wiring board. Thus, the component-embedded printed wiring board is realized having the necessary circuit wiring pattern for the electronic apparatus.

Since the circuit components 20 are in close contact with the component mounting surface when the component-embedded printed wiring board is mounted on the first base 10, no gaps to produce voids are formed between the components 20 and the mounting surface of the first base 10. Therefore, the various troubles attributable to voids can be avoided to realize the high-reliability component-embedded printed wiring board. Since the circuit components 20 are mounted in close contact with the component mounting surface of the first base 10 between the conductive patterns 13B on the mounting surface, the wiring board can be reduced in thickness. Since the circuit components 20 are in close contact with the component mounting surface of the first base 10 when it is mounted thereon, moreover, thin chip components can be prevented from being broken or damaged under pressure during lamination if they are mounted as the circuit components 20.

### Third Embodiment

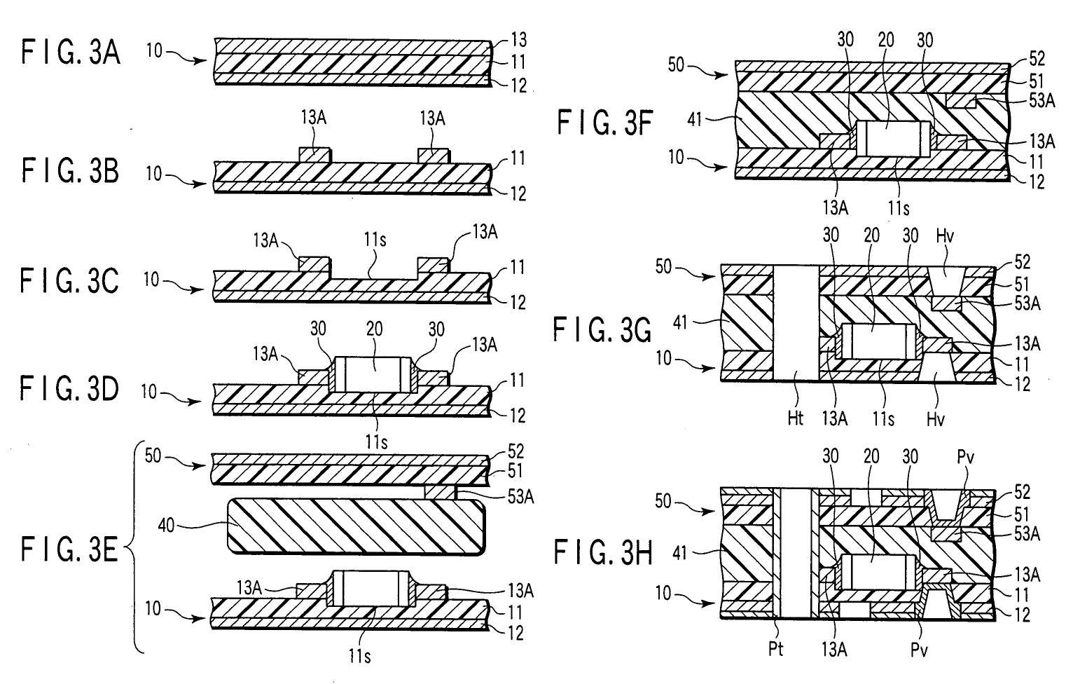

A component-embedded printed wiring board according to a third embodiment of the invention will be described together with manufacturing processes therefore with reference to FIGS. 3A to 3H.

FIGS. 3A to 3H show the manufacturing processes for the component-embedded printed wiring board according to the third embodiment of the invention. FIG. 3H shows a configuration of the component-embedded printed wiring board of the third embodiment, a product manufactured by the manufacturing processes.

As shown in FIG. 3H, the component-embedded printed wiring board according to the third embodiment of the invention comprises a first base 10, a resin material 41, a second base 50 that serves as another member, and a circuit component 20 to form an embedded chip component.

The first and second bases 10 and 50 and the resin material 41 are individually composed of the same members as the ones according to the first embodiment.

Electrically conductive patterns 13A are formed on a component mounting surface on the inner layer side of the first base 10 with a space therebetween for holding the circuit component 20. Formed in the component mounting surface, moreover, is a recess 11S in which a part of the circuit component 20 is held (or embedded).

The circuit component 20 is set between the conductive patterns 13A that are formed on the component mounting surface of the first base 10. The component 20 is in close contact with the bottom surface of the recess 11S when it is mounted on the first base 10.

Thus, in the wiring board structure of the third embodiment shown in FIG. 3H, the circuit component 20 is in close contact with the bottom surface of the recess 11S in the component mounting surface when it is mounted on the first base 10, so that no gap to produce voids is formed between the component 20 and the mounting surface of the first base 10. Even if any gap is formed, therefore, it is so narrow that it can be filled up with a small amount of filling or adhesive material. Accordingly, the various troubles attributable to voids can be avoided to realize the high-reliability component-embedded printed wiring board. Since the circuit component 20 is mounted in close contact with the bottom surface of the recess 11S between the conductive patterns 13A on the component mounting surface of the first base 10, the wiring board can be reduced in thickness. Since the circuit component 20 is mounted in close contact with the bottom surface of the recess 11S in the component mounting surface of the first base 10, moreover, a thin chip component can be prevented from being broken or damaged under pressure during lamination if it is mounted as the circuit component 20.

The component-embedded printed wiring board according to the third embodiment described above is manufactured by the processes shown in FIGS. 3A to 3H.

As shown in FIG. 3A, the first base 10 is prepared having conductive layers 12 and 13 for the formation of the conductive patterns on the opposite surfaces of a prepreg sheet 11. The second base 50 is prepared in like manner.

As shown in FIG. 3B, the pair of conductive patterns 13A are formed on the previously designed component mounting surface on the inner layer side of the first base 10 by selectively removing the conductive layer 13. The space between the conductive patterns 13A is designed so that the circuit component 20 can be confined thereto. The second base 50 is also formed with conductive patterns that comply with the pattern design requirements.

As shown in FIG. 3C, the recess 11S is formed in the component mounting surface on which the conductive patterns 13A are formed. Since the circuit component 20 must be mounted on the bottom surface of the recess 11S so as to be in close contact therewith, the bottom surface of the recess 11S is machined flat.

As shown in FIG. 3D, the circuit component 20 is mounted on the component mounting surface of the first base 10 between the conductive patterns 13A. In this mounting process, the circuit component 20 is in close contact with the bottom surface of recess 11S when it is mounted on the component mounting surface of the first base 10. Further, electrodes of the circuit component 20 are bonded to the conductive patterns 13A with the solder 30. If a gap is formed between the circuit component 20 and the recess 11S, depending on the shape of the mounted component 20, it is filled up with a low-viscosity filling or adhesive material.

As shown in FIG. 3E, an insulating layer of the resin material 41 that covers the circuit component 20 is formed on a pattern forming surface on the inner layer side of the first base 10, and the second base 50 is laminated over the first base 10 with this insulating layer between them. The pattern forming surface of the first base 10 is located opposite that surface of the second base 50 on which a conductive pattern 53A is formed.

As shown in FIG. 3F, the laminated members are integrated by being heated and pressurized. Thereupon, the second base 50 is laminated and integrated together with the first base 10 with the resin material 41 between them.

As shown in FIG. 3G, a through hole Ht, via holes Hv, etc. are formed in the component-embedded printed wiring board including the integrated members by hole boring based on drilling or laser machining.

As shown in FIG. 3H, the through hole Ht and the via holes Hv, which are bored in the process shown in FIG. 3G, and the respective surface layers (outermost layers) of the first and second bases 10 and 50 are subjected to plating and wiring. Thereupon, the through plug Pt and the via plugs Pv are formed together with a necessary circuit wiring pattern for the electronic apparatus that uses the component-embedded printed wiring board. Thus, the component-embedded printed wiring board is realized having the necessary circuit wiring pattern for the electronic apparatus.

Since the circuit component 20 is in close contact with the bottom surface of the recess 11S in the component mounting surface of the circuit component 20 when it is mounted on the first base 10, no gap to produce voids is formed between the component 20 and the mounting surface. Therefore, the various troubles attributable to voids can be avoided to realize the high-reliability component-embedded printed wiring board. Further, the wiring board can be reduced in thickness, since the circuit component 20 is mounted in close contact with the bottom surface of the recess 11S, which is lower in level than its surrounding area, between the conductive patterns 13A on the mounting surface of the first base 10. Since the circuit component 20 is in close contact with the bottom surface of the recess 11S on the component mounting surface of the first base 10 when it is mounted thereon, moreover, a thin chip component can be prevented from being broken or damaged under pressure during lamination if it is mounted as the circuit component 20.

In the third embodiment, furthermore, the conductive patterns 13A may be provided in the recess 11S. For example, the conductive patterns 13A are embedded in the first base 10, and the recess 11S is formed including the patterns 13A. In this arrangement, the conductive patterns 13A are located in the recess 11S, and the circuit component 20 is interposed and mounted by soldering between the patterns 13A in a manner such that it is in close contact with the bottom surface of the recess 11S.

### Fourth Embodiment

FIG. 4 shows a configuration of a principal part of a component-embedded printed wiring board according to a fourth embodiment of the invention.

In the component-embedded printed wiring board according to the fourth embodiment, as shown in FIG. 4, conductive patterns 13C, 13D and 13E to serve as component joining electrodes are formed on a previously designed component mounting surface on the inner layer side of a first base 10. A via plug to be connected to the conductive patterns 13D is formed in the first base 10. A pattern forming surface on the outer layer side of the first base 10 is formed with an external terminal electrode 12A on the via plug.

Circuit components 20 are provided individually between the conductive patterns 13C and 13D and between the conductive patterns 13D and 13E on the component mounting surface. Electrodes of the circuit components 20 are soldered to side or top surfaces of the conductive patterns. Each circuit component 20 is mounted in close contact with the component mounting surface of the first base 10.

The external terminal electrode 12A is connected to, for example, a terminal 61A of a BGA component 60 after a circuit board is constructed.

Also in this wiring board structure, the two circuit components 20 are individually in close contact with the component mounting surface when they are mounted on the first base 10, so that no gaps to produce voids are formed between the components 20 and the mounting surface of the first base 10. Therefore, the various troubles attributable to voids can be avoided to realize the high-reliability component-embedded printed wiring board. Further, the wiring board can be reduced in thickness, since the two circuit components 20 are mounted in close contact with the component mounting surface of the first base 10 between the conductive patterns 13C and 13D and between the conductive patterns 13D and 13E on the component mounting surface. Since the circuit components 20 are in close contact with the component mounting surface of the first base 10 when they are mounted thereon, moreover, thin chip components can be prevented from being broken or damaged under pressure during lamination if they are mounted as the circuit components 20.

### Fifth Embodiment

FIG. 5 shows a configuration of a principal part of a component-embedded printed wiring board according to a fifth embodiment of the invention.

In the foregoing first embodiment, the circuit component 20 is interposed between the conductive patterns 13A that are formed on the component mounting surface of the first base 10. In the component-embedded printed wiring board shown in FIG. 5, on the other hand, circuit components 20 are interposed individually between conductive patterns 13A on a component mounting surface of a first base 10 and between conductive patterns 53A on a component mounting surface of a second base 50. In this printed wiring board structure with a plurality of core members stacked in layers, a circuit component can be mounted on each of arbitrary opposite conductive layers in a manner such that it is interposed between the conductive patterns. Also in this case, the wiring board can be made thinner than the component mounting structure in which the circuit component is mounted on the conductive patterns (pads) by soldering. Since the circuit components 20 are individually in close contact with the respective component mounting surfaces of the first and second bases 10 and 50 when they are mounted thereon, moreover, thin chip components can be prevented from being broken or damaged under pressure during lamination if they are mounted as the circuit components 20.

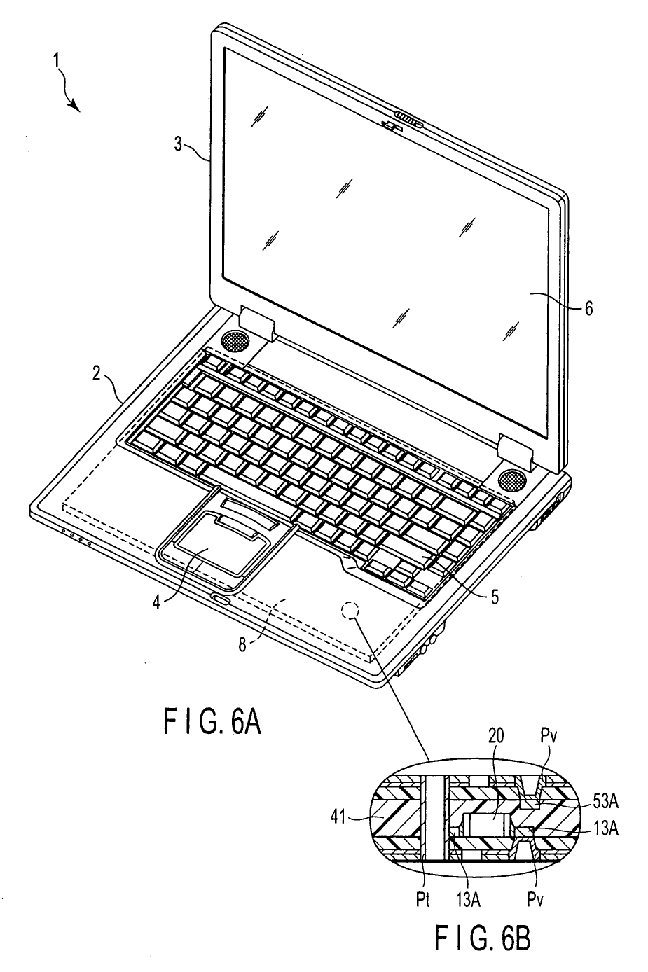

FIGS. 6A and 6B show a configuration of the electronic apparatus mounted with any of the component-embedded printed wiring boards according to the embodiments described above. This illustrated example is a case where the component-embedded printed wiring board manufactured according to the first embodiment is applied to a small electronic apparatus, such as a portable computer.

As shown in FIG. 6A, a body 2 of a portable computer 1 comprises a display housing 3 that is swingable by a hinge mechanism. The body 2 is provided with operating sections, such as a pointing device 4, keyboard 5, etc. The display housing 3 is provided with a display device 6, e.g., an LCD.

Further, the body 2 is provided with the operating sections, including the pointing device 4, keyboard 5, etc., and a printed circuit board (mother board) 8 in which a control circuit for controlling the display device 6 is incorporated. The printed circuit board 8 can be realized based on the component-embedded printed wiring board according to the first embodiment shown in FIG. 1G.

As shown in FIG. 6B, the component-embedded printed wiring board used in the printed circuit board 8 comprises a base 10 and a circuit component 20. Conductive patterns 13A that form component joining electrodes are provided on a component mounting surface of the base 10. The circuit component 20 is interposed between the conductive patterns 13A and mounted on the component mounting surface of the first base 10 so as to be in close contact therewith. In this wiring board structure, the circuit component 20 is in close contact with the component mounting surface when it is mounted on the base 10, so that no gap to produce voids are formed between the component 20 and the mounting surface of the base 10. Thus, the various troubles attributable to voids can be avoided to realize the high-reliability circuit board (printed circuit board 8), so that high-reliability operation can be expected.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A component-embedded printed wiring board comprising:
a base including a component mounting surface;
a pair of conductive patterns which are disposed on the component mounting surface of the base; and
a circuit component which is mounted on the base so as to be in close contact with the component mounting surface between the conductive patterns and electrically connected to the conductive patterns.

2. A component-embedded printed wiring board according to claim 1, wherein a plurality of the circuit components are provided between the pair of conductive patterns.

3. A component-embedded printed wiring board according to claim 1, wherein the circuit component is mounted between each pair of conductive patterns.

4. A component-embedded printed wiring board according to claim 1, wherein the base has a recess between the conductive patterns, the recess including a bottom surface which is lower in level than a surrounding area thereof, and the circuit component is mounted on the bottom surface of the recess.

5. A component-embedded printed wiring board according to claim 4, wherein a filling material or an adhesive material is provided between the bottom surface of the recess and the circuit component.

6. A component-embedded printed wiring board according to claim 1, wherein the pair of conductive patterns are electrode pads on which the circuit component is mounted or wiring patterns.

7. A component-embedded printed wiring board according to claim 6, wherein the pair of conductive patterns have, on side surfaces thereof, junction surfaces to which electrodes of the circuit component are soldered.

8. A component-embedded printed wiring board according to claim 7, wherein the circuit component is a chip component including electrodes on opposite ends thereof, individually, the electrodes of the chip component being soldered to respective side surfaces and/or top surfaces of the conductive patterns.

9. A component-embedded printed wiring board according to claim 1, which further comprises an insulating layer which covers the circuit component and another member laminated over the base with the insulating layer therebetween.

10. A component-embedded printed wiring board according to claim 9, wherein the other member has a pattern forming surface which, in conjunction with the base, forms a multilayer circuit.

11. A component-embedded printed wiring board according to claim 1, wherein a space between the base and the circuit component mounted thereon is impregnated with a filling material or an adhesive material.

12. A component mounting method for a component-embedded printed wiring board, in which a circuit component is mounted on a base including a component mounting surface, the component mounting method for a component-embedded printed wiring board comprising:
forming a pair of conductive patterns on the component mounting surface; and
mounting the circuit component on the base so as to be in close contact with the component mounting surface between the conductive patterns.

13. A component mounting method for a component-embedded printed wiring board according to claim 12, wherein electrodes of the circuit component are soldered to respective side surfaces and/or top surfaces of the conductive patterns when the circuit component is mounted thereon.

14. A component mounting method for a component-embedded printed wiring board according to claim 12, which further comprises forming a recess including a bottom surface which is lower in level than a surrounding area thereof between the conductive patterns, and wherein the circuit component is mounted on the bottom surface of the recess.

15. A component mounting method for a component-embedded printed wiring board according to claim 14, wherein electrodes of the circuit component are soldered to respective side surfaces and/or top surfaces of the conductive patterns when the circuit component is mounted thereon.

16. An electronic apparatus with a component-embedded printed wiring board which comprises a base including a component mounting surface, a pair of conductive patterns on the component mounting surface of the base, and a circuit component mounted on the base so as to be in close contact with the component mounting surface between the conductive patterns and electrically connected to the conductive patterns.
